(19) United States
(12) Patent Application Publication
(10) Pub. No.: US 2026/0112576 A1
(43) Pub. Date: Apr. 23, 2026

(54) PLASMA PROCESSING METHOD AND PLASMA PROCESSING APPARATUS

(71) Applicant: Samsung Electronics Co., Ltd., Suwon-si (KR)

(72) Inventors: Hyun Bae Kim, Suwon-si (KR); Sehun Song, Suwon-si (KR); Hyunjae Lee, Suwon-si (KR); Kyung-Sun Kim, Suwon-si (KR); Sang Ki Nam, Suwon-si (KR); Kwanhyung Lee, Suwon-si (KR); Juho Lee, Suwon-si (KR)

(73) Assignee: Samsung Electronics Co., Ltd., Suwon-si (KR)

(21) Appl. No.: 19/209,449

(22) Filed: May 15, 2025

(30) Foreign Application Priority Data
Oct. 17, 2024 (KR) 10-2024-0142334

(51) Int. Cl. H01J 37/32

(52) U.S. Cl. CPC H01J 37/32146; H01J 37/32174; H01J 37/32834; H01J 37/32935; H01J 2237/334

(57) ABSTRACT

A plasma processing apparatus according to an embodiment of the present invention may include a chamber configured to host a substrate, a source power supplying device configured to generate a plasma in the chamber by supplying the chamber with source power comprising a pulsed wave such that the source power has an on-duty state and an off-duty state, and a bias power supplying device configured to control a polarity of the plasma by supplying the chamber with bias power in at least a portion of the on-duty state of the source power and at least a portion of the off-duty state of the source power.

### CROSS-REFERENCE TO RELATED APPLICATIONS

The present application claims priority to and the benefit under 35 USC § 119(a)-(d) of Korean Patent Application No. 10-2024-0142334, filed on Oct. 17, 2024, in the Korean Intellectual Property Office, the entire content of which is incorporated herein by reference in its entirety.

### BACKGROUND

In a manufacturing process of a semiconductor device, plasma processing may be performed in various processes such as a deposition process, an etching process, and a cleaning process. Semiconductor devices are becoming increasingly highly integrated, and as a result, a line width of a pattern of the semiconductor device is decreasing and an aspect ratio of the pattern is increasing. A plasma processing apparatus and a plasma processing method for forming a fine structure of the semiconductor device with high reliability are required.

### SUMMARY

The present invention is directed to providing a plasma processing device and a plasma processing method that can form a fine structure of a semiconductor device with high reliability.

The present invention is directed to providing a plasma processing device and a plasma processing method that can effectively utilize not only positive ions but also negative ions of plasma during plasma processing.

A plasma processing apparatus according to an embodiment of the present invention may include a chamber configured to host a substrate, a source power supplying device configured to generate a plasma in the chamber by supplying the chamber with source power comprising a pulsed wave such that the source power has an on-duty state and an off-duty state, and a bias power supplying device configured to control a polarity of the plasma by supplying the chamber with bias power in at least a portion of the on-duty state of the source power and at least a portion of the off-duty state of the source power.

The plasma processing apparatus may further comprise an exhaust device configured to exhaust the chamber during a subportion of the portion of the off-duty state in which the bias power is in an off-duty state.

The bias power may comprise a pulse-modulated sinusoidal wave or a pulse-modulated non-sinusoidal wave.

The pulse-modulated non-sinusoidal wave may comprise a pulse portion having a positive bias voltage and a ramp portion having a negative bias voltage varying with a negative slope.

The source power supplying device may be configured to supply the chamber with the source power having three states, and the bias power supplying device may be configured to supply the chamber with the bias power having two states or three states.

The three states of the source power may comprise a first on-duty state, a second on-duty state, and the off-duty state, the two states of the bias power may comprise an on-duty state and an off-duty state, and the bias power supplying device may be configured to supply the chamber with the bias power in the on-duty state in at least portion of the second on-duty state of the source power and at least a portion of the off-duty state of the source power.

The first on-duty state of the source power and the second on-duty state of the source power may be contiguous, and a voltage magnitude of the source power in the first on-duty state may differ from a voltage magnitude of the source power in the second on-duty state.

The three states of the power source may comprise a first on-duty state, a second on-duty state, and the off-duty state, the three states of the bias power may comprise a third on-duty state, a fourth on-duty state, and an off-duty state, the bias power supplying device may be configured to supply the chamber with the bias power in the third on-duty state in at least a portion of the first on-duty state of the source power and at least a portion of the second on-duty state of the source power, and the bias power supplying device may be configured to supply the chamber with the bias power in the fourth on-duty state in at least a portion of the second on-duty state of the source power and at least a portion of the off-duty state of the source power.

The first on-duty state of the source power and the second on-duty state of the source power may be contiguous, and a voltage magnitude of the source power in the first on-duty state may differ from a voltage magnitude of the source power in the second on-duty state, and the third on-duty state of the bias power and the fourth on-duty state of the bias power are contiguous, and a voltage magnitude of the bias power in the third on-duty state may be smaller than a voltage magnitude of the bias power in the fourth on-duty state.

The plasma processing apparatus may further comprise a control device configured to transmit a command including a delay time to the bias power supplying device.

The control device may be configured to transmit a mode command based on the number of on-duty state of the bias power to the bias power supplying device.

The bias power supplying device may be configured to supply the chamber with the bias power in an on-duty state after the delay time has elapsed from a rising edge of a sync pulse.

The control device may be configured to individually control an on-duty state of each of the source power and the bias power.

The plasma processing apparatus may further comprise an exhaust device configured to perform exhausting of the chamber, the exhaust device may be configured to receive a control command including the delay time and a duration time of an on-duty state of the bias power from the control device.

The exhaust device may be configured to receive a sync pulse from a sync pulse generating device.

The exhaust device may be configured to receive a trigger signal from each of the source power supplying device and the bias power supplying device and to perform exhausting of the chamber based on the trigger signal.

A plasma processing apparatus according to an embodiment of the present invention may include a chamber configured to host a substrate, a top electrode including a plurality of coils, a substrate stage including a bottom electrode, the substrate stage being configured to support the substrate, a source power supplying device configured to generate a plasma in the chamber by supplying the top electrode with source power comprising a pulsed wave such that the source power has an on-duty state and an off-duty state, and a bias power supplying device configured to control a polarity of the plasma by supplying the bottom electrode with bias power in at least a portion of the on-duty state of the source power and at least a portion of the off-duty state of the source power.

The bias power supplying device may include a direct current (DC) power supplier configured to generate a DC voltage and a modulator configured to ramp a portion of the bias power.

A plasma processing apparatus according to an embodiment of the present invention may include a chamber configured to host a substrate; a top electrode to which ground potential is applied, a substrate stage including a bottom electrode, the substrate stage being configured to support the substrate, a source power supplying device configured to generate a plasma in the chamber by generating source power comprising a pulsed wave such that the source power has an on-duty state and an off-duty state, a bias power supplying device configured to control a polarity of the plasma by generating bias power, and a mixer configured to generate a signal by mixing the source power and the bias power, and to apply the signal to the bottom electrode, wherein the bias power supplying device is configured to supply the bias power to the mixer in at least a portion of the on-duty state of the source power and at least a portion of the off-duty state of the source power.

The mixer may be configured to supply the bottom electrode with a signal that mixes the bias power in an on-duty state and the source power in the on-duty state in a first time interval and to supply the bottom electrode with a signal that mixes the bias power in the on-duty state and the source power in the off-duty state in a second time interval.

A plasma processing method comprising placing a substrate in a chamber; generating a plasma in the chamber by supplying the chamber with source power comprising a pulsed wave such that the source power has an on-duty state and an off-duty state; and controlling a polarity of the plasma by supplying the chamber with bias power in at least a portion of the on-duty state of the source power and at least a portion of the off-duty state of the source power.

The plasma processing method may further comprise exhausting the chamber during a subportion of the portion of the off-duty state in which the bias power is in an off-duty state.

The bias power may comprise a pulse-modulated sinusoidal wave or a pulse-modulated non-sinusoidal wave.

The bias power may comprise a pulse-modulated sinusoidal wave or a pulse-modulated non-sinusoidal wave.

The pulse-modulated non-sinusoidal wave may comprise a pulse portion having a positive bias voltage and a ramp portion having a negative bias voltage varying with a negative slope.

Supplying the chamber with source power may comprise supplying the chamber with the source power having three states, and supplying the chamber with bias power may comprise supplying the chamber with the bias power having two states or three states.

The three states of the source power may comprise a first on-duty state, a second on-duty state, and the off-duty state, the two states of the bias power may comprise an on-duty state and an off-duty state, and supplying the chamber with bias power may comprise supplying the chamber with the bias power in the on-duty state in at least portion of the second on-duty state of the source power and at least a portion of the off-duty state of the source power.

The first on-duty state of the source power and the second on-duty state of the source power may be contiguous, and a voltage magnitude of the source power in the first on-duty state may differ from a voltage magnitude of the source power in the second on-duty state.

The three states of the power source may comprise a first on-duty state, a second on-duty state, and the off-duty state, the three states of the bias power may comprise a third on-duty state, a fourth on-duty state, and an off-duty state, supplying the chamber with bias power may comprise supplying the chamber with the bias power in the third on-duty state in at least a portion of the first on-duty state of the source power and at least a portion of the second on-duty state of the source power, and supplying the chamber with bias power may comprise supplying the chamber with the bias power in the fourth on-duty state in at least a portion of the second on-duty state of the source power and at least a portion of the off-duty state of the source power.

The first on-duty state of the source power and the second on-duty state of the source power may be contiguous, and a voltage magnitude of the source power in the first on-duty state may differ from a voltage magnitude of the source power in the second on-duty state, and the third on-duty state of the bias power and the fourth on-duty state of the bias power are contiguous, and a voltage magnitude of the bias power in the third on-duty state may be smaller than a voltage magnitude of the bias power in the fourth on-duty state.

The plasma processing method may further comprise transmitting a command including a delay time to a bias power supplying device that performs the supplying of the chamber with bias power.

The plasma processing method may further comprise transmitting a mode command based on the number of on-duty state of the bias power to the bias power supplying device.

The bias power supplying device may be configured to supply the chamber with the bias power in an on-duty state after the delay time has elapsed from a rising edge of a sync pulse.

### BRIEF DESCRIPTION OF DRAWINGS

FIG. 1 is a block diagram conceptually describing a plasma processing apparatus according to one embodiment of the present invention.

FIGS. 2 to 5 are diagrams exemplarily describing configurations of plasma processing apparatuses according to embodiments of the present invention.

FIGS. 6 to 12 are diagrams describing waveforms and timings of source power and bias power according to embodiments of the present invention.

FIG. 13 is a flowchart describing a plasma processing method according to one embodiment of the present invention.

FIGS. 14 to 16 are views describing some steps of a plasma processing method according to an embodiment of the present invention.

### DETAILED DESCRIPTION

Hereinafter, embodiments of the present invention will be described clearly and in detail so that those skilled in the art can easily practice the present invention.

The inventors have recognized and appreciated that conventional plasma processing devices and methods, in which plasma-based processing is performed using ions of one polarity (whether negative or positive), are inefficient. Consider for example a conventional plasma etching device, in which positive ions are used to etch a portion of a substrate, for example to form a recess. As the positive ions strike the surface of the substrate, the ions transfer part of their energy to the surface atoms, causing some of the surface atoms of the substrate to ionize. This poses a challenge. As subsequent positive ions strike the surface, their effectiveness in etching the substrate is diminished relative to the initial positive ions. As a result, the etching efficiency diminishes with the depth. Deeper atoms are more difficult to etch than shallower atoms.

Recognizing these limitations, the inventors have developed plasma processing devices and methods that leverage both ion polarities. Consider for example the plasma etching device described above. Initially, etching is performed using a first polarity (e.g., positive ions). Subsequently, as the efficiency of the positive ions in etching the substrate diminishes, etching is performed using a second polarity (e.g., negative ions). As a result, the efficiency of the etching device is increased.

In some embodiments, as described in detail further below, swapping the polarity of the ions can be accomplished by supplying bias power in part during the on-duty state of the source power and in part during the off-duty state of the source power. Supplying bias power during the on-duty state of the source power leads to processing based primarily on one polarity (e.g., positive ions) while supplying bias power during the off-duty state of the source power leads to processing based primarily on the opposite polarity (e.g., negative ions).

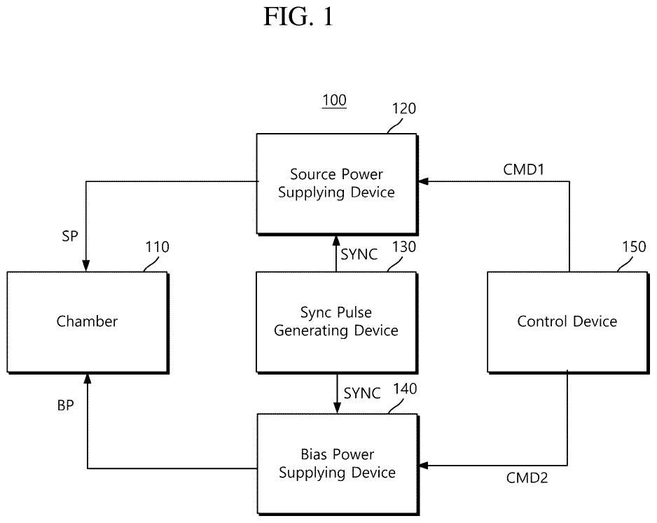

FIG. 1 is a block diagram describing a plasma processing apparatus 100 according to one embodiment of the present invention. Referring to FIG. 1, the plasma processing apparatus 100 according to one embodiment of the present invention will be described.

FIG. 1 conceptually shows a configuration of the plasma processing apparatus 100. Referring to FIG. 1, the plasma processing apparatus 100 may perform plasma processing on a substrate. For example, the plasma processing apparatus 100 may perform an etching process, a deposition process, an ashing process, and the like on the substrate. Although embodiments of the present specification exemplarily describe the etching process of the plasma processing apparatus 100, the present invention is not limited to the etching processes, and the plasma processing apparatus 100 may be configured to perform the deposition process, the ashing process, and the like on the substrate.

In one embodiment, the substrate may be a semiconductor wafer substrate. Alternatively, the substrate may be a glass substrate.

The plasma processing apparatus 100 of FIG. 1 may be implemented as an inductively coupled plasma (ICP) processing apparatus, a capacitive coupled plasma (CCP) processing apparatus, an electron cyclotron resonance (ECR) plasma processing apparatus, or a helical plasma processing apparatus. The present invention is not limited to a specific type of plasma processing apparatus and may be implemented in any plasma processing apparatus that uses source power and bias power.

Referring to FIG. 1, the plasma processing apparatus 100 may include a chamber 110, a source power supplying device 120, a sync pulse generating device 130, a bias power supplying device 140, and a control device 150. In addition, the plasma processing apparatus 100 may include an electrostatic chuck voltage supplying device, a gas supplying device, and an exhaust device, etc. according to embodiments.

The chamber 110 may host and a substrate and, as such, may provide a processing space in which plasma processing may be performed on a substrate. The chamber 110 may be a vacuum chamber having a cylindrical shape. The chamber 110 may be at least partially made of a material such as aluminum or stainless steel. In one embodiment, the chamber 110 may include a lower chamber structure and an upper chamber structure.

The chamber 110 may receive the source power with a pulsed wave (e.g., pulse-modulated sinusoidal wave or other types of pulsed waves) from the source power supplying device 120. Given the pulsed nature of the wave, the source power has an on-duty state and an off-duty state. The chamber 110 may generate plasma in the processing space using the source power SP.

The chamber 110 may receive the bias power for controlling the polarity of the plasma (e.g., for controlling whether plasma ions are positive ions or negative ions) from the bias power supplying device 140. The bias power provided to the chamber 110 from the bias power supplying device 140 may be the pulse-modulated bias power. The chamber 110 may control plasma processing so that the generated plasma ions are incident on the substrate using the bias power BP.

In one embodiment, the bias power may be the bias power with a pulsed wave (e.g., a pulse-modulated sinusoidal wave or non-sinusoidal wave).

In one embodiment, each of the source power and the bias power may be supplied to a different electrode of the chamber 110.

In one embodiment, the source power and the bias power may be mixed in a mixer, and the mixed power may be supplied to one electrode of the chamber 110. In this case, the other electrode of the chamber 110 may operate as a ground electrode.

The source power supplying device 120 and the bias power supplying device 140 may receive a sync pulse SYNC from the sync pulse generating device 130.

The source power supplying device 120 may control an on-duty state and an off-duty state of the source power pulse based on the sync pulse.

The control device 150 may transmit a first control command CMD1 to the source power supplying device 120 and transmit a second control command CMD2 to the bias power supplying device 140.

The source power supplying device 120 may control the on-duty state and the off-duty state of a pulse of the source power based on the first control command CMD1. For example, based on the first control command CMD1, the source power supplying device 120 may control at least one of lengths, voltage magnitudes, and numbers of the on-duties and/or the off-duties of the source power SP.

The bias power supplying device 140 may control an on-duty state and an off-duty state of a pulse of the bias power based on the second control command CMD2. For example, based on the second control command CMD2, the bias power supplying device 140 may control at least one of lengths, voltage magnitudes, and numbers of the on-duties and/or the off-duties of the bias power BP.

The bias power supplying device 140 of the plasma processing apparatus 100 according to an embodiment of the present invention may supply the chamber 110 with the bias power in at least a portion of the on-duty state of the source power and at least a portion of the off-duty state of the source power.

In one embodiment, the source power may include two states including one on-duty state and one off-duty state per each cycle. That is, the source power may be implemented as the source power of two states. In this case, the bias power supplying device 140 may supply the chamber 110 with the bias power in both at least a portion of one on-duty state and at least a portion of one off-duty state of each cycle of the source power.

In one embodiment, the source power may include three states including two on-duties and one off-duty state per each cycle. That is, the source power may be implemented as the source power of three states. In this case, the two on-duties may include a first on-duty state and a second on-duty state, and the source power may have different voltage magnitudes in the first on-duty state and the second on-duty state. That is, a voltage magnitude of the source power of the first on-duty state may differ from a voltage magnitude of the source power of the second on-duty state. The source power supplying device 120 may provide the source power of the first on-duty state to the chamber 110 and then provide the source power of the second on-duty state to the chamber 110. Thereafter, the source power supplying device 120 may provide the source power of the off-duty state to the chamber 110. That is, the source power of the first on-duty state and the source power of the second on-duty state may be sequentially provided to the chamber 110. In this case, the bias power supplying device 140 may supply the chamber 110 with the bias power in both at least a portion of one on-duty state and at least a portion of one off-duty state of each cycle of the source power. For example, the bias power supplying device 140 may supply the chamber 110 with the bias power in both at least a portion of the second on-duty state and at least a portion of the off-duty state.

In one embodiment, the bias power may include two states including one on-duty state and one off-duty state for each cycle, or three states including two on-duties and one off-duty state per each cycle.

In one embodiment, when the bias power includes two states, the bias power of the on-duty state may be supplied to the chamber 110 in at least a portion of the on-duty state of the source power and at least a portion of the off-duty state of the source power.

In one embodiment, when the bias power includes two states, the bias power of a third on-duty state may be supplied to the chamber 110 in at least a portion of at least one on-duty state of the source power, and the bias power of a fourth on-duty state may be supplied to the chamber 110 in at least a portion of one on-duty state and at least a portion of the off-duty state of the source power.

That is, the bias power supplying device 140 according to an embodiment of the present invention may supply the bias power of the on-duty state to the chamber 110 not only in a portion in which the source power of the on-duty state is supplied to the chamber 110 but also in at least a portion in which the source power of the off-duty state is supplied to the chamber 110.

A portion of the plasma generated based on the source power in the processing space of the chamber 110 may remain even in a portion in which the source power of the off-duty state is supplied to the chamber 110. Therefore, since the bias power is supplied to the chamber 110 in at least a portion in which the source power of the off-duty state is supplied to the chamber 110, negative ions of the remaining plasma due to the difference between a wafer voltage and a plasma voltage may be used for processing the substrate. For example, in the etching process, the negative ions may be incident on a portion etched in a depth direction of the substrate to perform etching. The portion etched in the depth direction may include a recess.

The plasma processing apparatus 100 according to an embodiment of the present invention may perform plasma processing by positive ions by supplying the bias power of the on-duty state in at least a subportion of the portion in which the source power of the on-duty state is supplied to the chamber 110. Furthermore, the plasma processing apparatus 100 may perform plasma processing by the negative ions by supplying the chamber 110 with the bias power of the on-duty state in at least a subportion of the portion in which the source power of the off-duty state is supplied. Therefore, the plasma processing apparatus 100 may perform plasma processing more effectively by using each of the positive ions and the negative ions for plasma processing.

In addition, in a plasma processing apparatus according to an alternative technology that can be adopted, positive charges may be charged on the substrate during plasma processing by the positive ions. In this case, due to the positive charges charged on the substrate, the efficiency of plasma processing by the positive ions may decrease at a deep place. In contrast, the plasma processing apparatus 100 of the present invention can prevent plasma processing efficiency from being degraded by the positive charges charged on the substrate by performing the plasma processing by the negative ions following the plasma processing by the positive ions.

In one embodiment, the control device 150 may include information indicating the number of on-duties included in one cycle of the source power SP in the first control command CMD1. For example, the control device 150 may transmit the first control command CMD1 to the source power supplying device 120 to supply the chamber with the source power having two states or the source power having three states.

In one embodiment, the control device 150 may include information indicating the number of on-duties included in one cycle of the bias power BP in the second control command CMD2. For example, the control device 150 may transmit the second control command CMD2 to the bias power supplying device 140 to supply the chamber with the source power having two states or the bias power BP having three states.

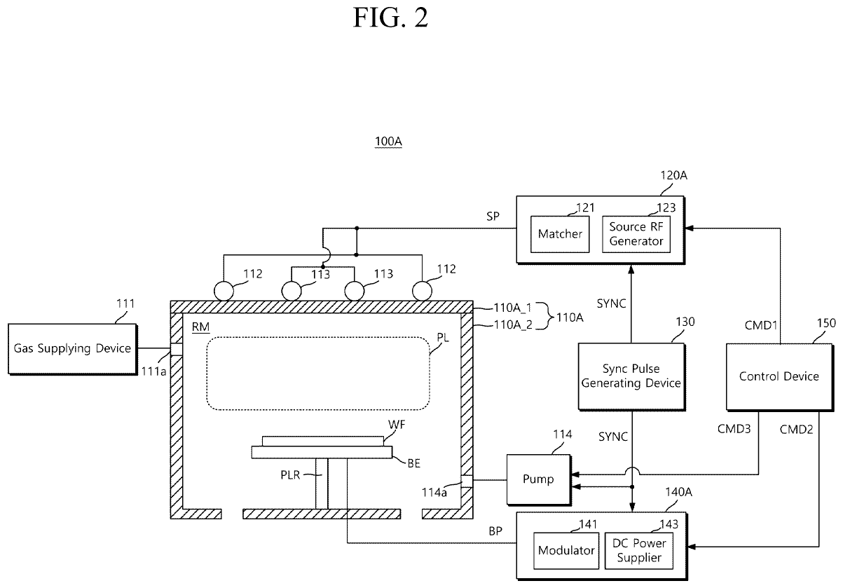

FIG. 2 is a block diagram describing a plasma processing apparatus 100A implemented as an ICP processing apparatus according to one embodiment of the present invention. The plasma processing apparatus 100A of FIG. 2 may correspond to the plasma processing apparatus 100 of FIG. 1. Referring to FIG. 2, the plasma processing apparatus 100A according to one embodiment of the present invention will be described. Detailed description of portions overlapping or similar to those described with reference to FIG. 1 will be omitted.

Referring to FIG. 2, the plasma processing apparatus 100A may include a chamber 110A, a gas supplying device 111, a source power supplying device 120A, the sync pulse generating device 130, a bias power supplying device 140A, and the control device 150.

The chamber 110A may include a processing space RM in which plasma processing may be performed on a substrate WF. The processing space RM may be a closed space for performing plasma processing. The chamber 110A may be a vacuum chamber having a cylindrical shape. The chamber 110A may be at least partially made of a metallic material such as aluminum or stainless steel. The chamber 110A may include an upper chamber structure 110A_1 and a lower chamber structure 110A_2.

The chamber 110A may include a top electrode composed of a plurality of coils 112 and 113. The plurality of coils 112 and 113 may include an inner coil 112 and an outer coil 113. The plurality of coils 112 and 113 may have a helical shape or a concentric shape. Although FIG. 2 exemplarily shows that each of the inner coil 112 and the outer coil 113 includes two coils, shapes and configurations of the inner coil 112 and the outer coil 113 are not limited to the shape shown in FIG. 2.

The source power SP may be supplied from the source power supplying device 120A to the chamber 110A through the inner coil 112 and the outer coil 113. The source power SP supplied through the inner coil 112 and the outer coil 113 may generate inductively coupled plasma (ICP) in the processing space RM of the chamber 110A.

The source power SP supplied to the chamber 110A through the inner coil 112 and the outer coil 113 may be a pulse-modulated sinusoidal wave. That is, the source power may be a pulsing sinusoidal wave.

The gas supplying device 111 may supply various gases required for plasma processing to an upper portion and/or side surfaces of the chamber 110A through at least one gas supplying pipe 111a. FIG. 2 examplarily shows a form in which the gas supplying pipe 111a passes through the side surface of the chamber 110A. However, the gas supplying pipe 111a may be implemented in a form that vertically passes through the chamber 110A or supplies gas in the processing space RM inside the chamber 110A in a vertical direction. For example, the gas supplying pipe 111a may be implemented as a form of a vertical gas supplying pipe passing through the upper chamber structure 110A_1.

The gas supplying device 111 may supply different gases at a desired ratio. The gas supplying device 111 may store various types of gases, and various types of gases may be supplied to the processing space RM of the chamber 110A through a plurality of gas lines that are each connected to at least one gas supplying pipe 111a.

An exhaust device 114 may be connected to an exhaust port 114a installed in the lower chamber structure 110A_2 of the chamber 110A through an exhaust pipe. The exhaust device 114 may include a vacuum pump. For example, the vacuum pump may be a turbo molecular pump. The exhaust device 114 may perform exhausting of the processing space RM, and the plasma processing apparatus 100A may control the pressure of the processing space RM inside the chamber 110A through the exhausting. That is, the plasma processing apparatus 100A may control the degree of vacuum of the processing space RM. The control device 150 may transmit a control command CMD3 including a numerical value of a desired pressure inside the chamber 110A.

In addition, the exhaust device 114 may discharge process by-products and residual process gases that are generated in the processing space RM of the chamber 110A due to plasma processing to the outside of the chamber 110A.

The plasma processing apparatus 100A according to an embodiment of the present invention may control the exhaust device 114 to perform the exhausting of the chamber 110A in at least a portion of an off-duty state of the source power SP and at least a portion of an off-duty state of the bias power BP. Therefore, plasma processing using negative ions may be performed based on the bias power BP of an on-duty state in at least a portion of an off-duty state of the source power SP, and the exhausting of the chamber 110A may be performed in the other portions of the off-duty state of the source power SP. In one embodiment, in order to perform the exhausting of the chamber 110A, the exhaust device 114 may receive a sync pulse SYNC from the sync pulse generating device 130 and receive the control command CMD3 including a delay time and an on-duty state duration time of the bias power BP from the control device 150. Therefore, the exhaust device 114 may accurately perform the exhausting of the chamber 110A in a portion in which both the source power SP and the bias power BP are the off-duty state. In another embodiment, the chamber 110A may receive trigger signals from the source power supplying device 120A and the bias power supplying device 140A, and based on the trigger signals, the chamber 110A may accurately perform the exhausting of the chamber 110A in the portion in which both the source power SP and the bias power BP are the off-duty state.

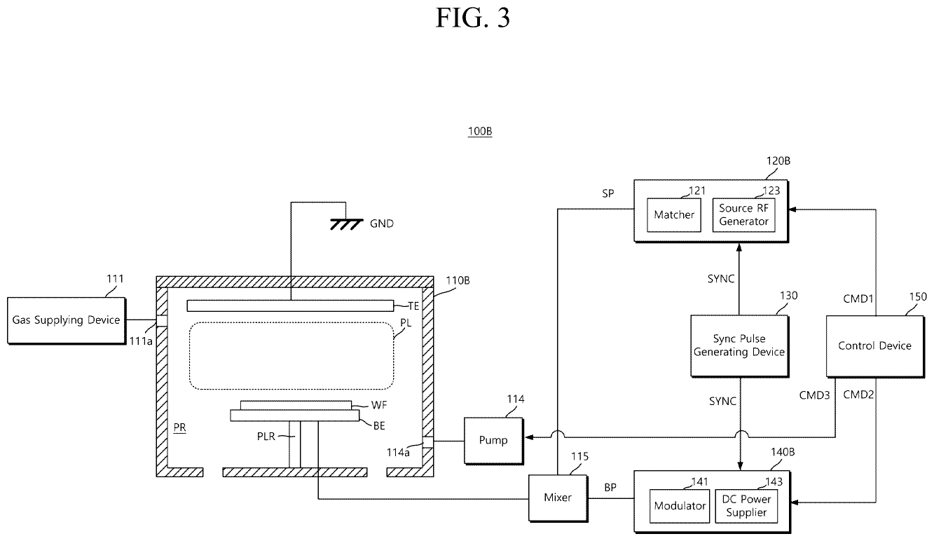

The bias power supplying device 140A may receive a control command CMD2 including the delay time and the on-duty state duration time of the bias power BP from the control device 150. Based on the control command CMD2 received from the control device 150, the bias power supplying device 140A may supply the chamber 110A with the bias power BP having the on-duty state during the on-duty state duration time after the delay time from a rising edge of the sync pulse SYNC. Therefore, the bias power supplying device 140A may be independently controlled separately from the source power supplying device 120A based on the control command CMD2 including the delay time and the on-duty state duration time of the bias power BP. In the embodiments of FIGS. 3 to 5, the bias power supplying device may be independently controlled separately from the source power supplying device by the control device 150.

The source power supplying device 120A may include a matcher 121 and a source RF generator 123. The source RF generator 123 may generate a radio frequency (RF) signal. The matcher 121 may match the impedance of the RF signal generated from the source RF generator 123.

The control device 150 may transmit a control command CMD1 for controlling the source power SP to the source power supplying device 120A. The source power supplying device 120A may control the source RF generator 123 and the matcher 121 based on the control command CMD1 received from the control device 150, and apply the source power SP to the plurality of coils 112 and 113. For example, the source power SP may be a pulse-modulated sinusoidal wave within a frequency range of about 13 MHz to 60 MHz. The frequency range of the source power SP is not limited to the above numerical values.

When the source power SP is applied to the plurality of coils 112 and 113, an electromagnetic field induced by the plurality of coils 112 and 113 may be applied to the gas in the chamber 110A, and as a result, plasma PL may be generated.

The substrate WF may be disposed on a substrate stage including a bottom electrode BE. The substrate stage including the bottom electrode BE may be constituted to support the substrate WF. In one embodiment, the substrate stage may include an electrostatic chuck for fixing the substrate WF by an electrostatic suction force. The electrostatic chuck may generate an electrostatic force by a DC voltage supplied from a separate DC power source, and may adsorb and fix the substrate WF using the electrostatic force. The substrate stage including the bottom electrode BE may move up and down by a driving unit PLR. For example, the substrate stage may move in an upward direction that is an inward direction of the chamber 110A or in a downward direction that is an outward direction of the chamber 110A. When the substrate stage moves in the upward direction, the substrate stage may become relatively closer to the plasma PL.

The control device 150 may transmit the control commands CMD1 and CMD2 for controlling the source power supplying device 120A and the bias power supplying device 140A to the source power supplying device 120A and the bias power supplying device 140A, respectively. That is, the bias power supplying device 140 may be controlled independently of the source power supplying device 120. The control device 150 may include a general-purpose processor or a dedicated processor. The control device 150 may include a memory device. The control device 150 may generate the control commands CMD1, CMD2, and CMD3 based on a program and/or firmware stored in the memory device. The control device 150 may include a display device and may receive an input of a user through the display device and/or an input device. The input device may include input devices such as a mouse and a keyboard that are generally connected to a computer device, and is not particularly limited thereto. The memory device may include at least one preset recipe. The control device 150 may generate the control commands CMD1, CMD2, and CMD3 based on the recipe and control the source power supplying device 120A, the bias power supplying device 140A, the gas supplying device 111, and/or the exhaust device 114.

The bias power supplying device 140A may supply the bias power BP to the bottom electrode BE. The plasma processing apparatus 100A may control a wafer voltage and an ion energy distribution of a surface of the substrate WF by controlling a voltage waveform, on-duty state, and off-duty state of the bias power BP. As a result, the plasma processing apparatus 100A may control plasma processing. For example, by controlling the bias power BP, the plasma processing apparatus 100A may control an etch rate, etc. in the etching process using plasma processing.

The bias power supplying device 140A according to an embodiment of the present invention with reference to FIG. 2 may supply the bottom electrode BE with the bias power BP in a form of a pulse-modulated non-sinusoidal wave. The bias power BP may be a pulse-modulated non-sinusoidal wave in a frequency range of 200 KHz to 2 MHz. The frequency range of the bias power BP is not limited to the above numerical values.

In one embodiment, the bias power BP may have a form of a pulse-modulated rectangular wave.

In one embodiment, the bias power BP may have a form of a pulse-modulated non-sinusoidal wave that includes a pulse portion having a positive bias voltage and a ramp portion having a negative bias voltage varying with a negative slope. The ramp portion may be located between pulse portion s having a constant magnitude of a positive bias voltage.

The bias power supplying device 140A may include a modulator 141 and a direct current (DC) power supplier 143. The modulator 141 may include a pulse adjustment circuit and a ramp adjustment circuit. The DC power supplier 143 may generate a DC voltage and supply the DC voltage to the modulator 141. The modulator 141 may control the DC voltage using power device switches to generate the bias power BP having a voltage waveform of a non-sinusoidal wave.

For example, the modulator 141 may generate the bias power BP in a form of a rectangular wave in which a constant magnitude of a positive voltage and a constant magnitude of a negative voltage alternate.

Alternatively, the modulator 141 may generate the bias power BP in a form in which a pulse portion having a constant magnitude of a positive voltage and a ramp portion having a negative bias voltage varying with a negative slope alternate. When the bias power BP includes the ramp portion having a negative bias voltage varying with a negative slope, the wafer voltage of the substrate WF charged by the positive ions of the plasma can be effectively controlled.

The bias power supplying device 140A may generate the bias power BP so that the on-duty state of the bias power BP is located in at least a portion of the on-duty state of the source power SP and at least a portion of the off-duty state of the source power SP.

In one embodiment, the bias power BP may maintain the on-duty state in all portions of the on-duty state of the source power SP. Alternatively, in another embodiment, the bias power BP may maintain the on-duty state only in a portion of the on-duty state of the source power SP.

In one embodiment, the bias power BP may maintain the on-duty state in a portion of the off-duty state of the source power SP and maintain the off-duty state in the other portions of the off-duty state of the source power SP.

The plasma processing apparatus 100A can perform plasma processing more effectively by using each of the positive ions and the negative ions for the plasma processing. In addition, the plasma processing apparatus 100A can prevent plasma processing efficiency from being degraded by the positive charges charged on the substrate by performing the plasma processing by the negative ions following the plasma processing by the positive ions.

In addition, when the plasma processing apparatus 100A supplies the chamber 110A with the bias power BP in a form of a pulse-modulated non-sinusoidal wave, which includes the ramp portion, the plasma processing apparatus 100A can effectively control the wafer voltage of the substrate WF charged by the positive ions of the plasma.

FIG. 3 is a block diagram describing a plasma processing apparatus 100B implemented as a CCP processing apparatus according to one embodiment of the present invention. The plasma processing apparatus 100B of FIG. 3 may correspond to the plasma processing apparatus 100 of FIG. 1. Referring to FIG. 3, the plasma processing apparatus 100B according to one embodiment of the present invention will be described. Detailed description of portions overlapping or similar to those described with reference to FIGS. 1 and 2 will be omitted. The plasma processing apparatus 100B will be described with reference to FIG. 3 by focusing on differences from the plasma processing apparatus 100A of FIG. 2.

Referring to FIG. 3, the plasma processing apparatus 100B shows a capacitive coupled plasma (CCP) processing apparatus in which ground potential is applied to a top electrode TE and the source power SP and the bias power BP are applied to the bottom electrode BE.

A source power supplying device 120B may generate the source power SP in a form of a pulse-modulated sinusoidal wave and supply the source power SP to the mixer 115. The bias power supplying device 140B may generate the bias power BP in a form of a pulse-modulated non-sinusoidal wave and supply the bias power BP to the mixer 115. Similar to the embodiment described with reference to FIG. 2, the bias power BP may be a non-sinusoidal wave in a form of a pulse-modulated rectangular wave or a non-sinusoidal wave including a ramp portion having a negative bias voltage varying with a negative slope.

The mixer 115 may apply a signal that mixes the source power SP and the bias power BP to the bottom electrode BE.

Similar to the embodiment described with reference to FIG. 2, the bias power supplying device 140B according to an embodiment of the present invention may generate the bias power BP so that the on-duty state of the bias power BP is located in at least a portion of the on-duty state of the source power SP and at least a portion of the off-duty state of the source power SP.

The mixer 115 may supply a signal that mixes the bias power BP of the on-duty state and the source power SP of the on-duty state to the bottom electrode BE in a first time portion and supply a signal that mixes the bias power BP of the on-duty state and the source power SP of the off-duty state to the bottom electrode BE in a second time interval. The plasma processing apparatus 100B may control the exhaust device 114 to perform exhausting of a chamber 110B in at least a portion of the off-duty state of the source power SP and at least a portion of the off-duty state of the bias power BP. In one embodiment, in order to perform the exhausting of the chamber 110B, the exhaust device 114 may receive a sync pulse SYNC from the sync pulse generating device 130 and receive the control command CMD3 including a delay time and an on-duty state duration time of the bias power BP from the control device 150.

The bias power supplying device 140B may receive the control command CMD2 including the delay time and the on-duty state duration time of the bias power BP from the control device 150. Based on the control command CMD2 received from the control device 150, the bias power supplying device 140B may supply the chamber 110B with the bias power BP having the on-duty state during the on-duty state duration time after the delay time from a rising edge of the sync pulse SYNC.

The plasma processing apparatus 100B can perform plasma processing more effectively by using each of the positive ions and the negative ions for plasma processing. In addition, the plasma processing apparatus 100B can prevent plasma processing efficiency from being degraded by the positive charges charged on the substrate by performing the plasma processing by the negative ions following the plasma processing by the positive ions.

In addition, when the plasma processing apparatus 100B supplies the chamber 110B with the bias power BP in a form of a pulse-modulated non-sinusoidal wave, which includes the ramp portion, the plasma processing apparatus 100B can effectively control the wafer voltage of the substrate WF charged by the positive ions of the plasma.

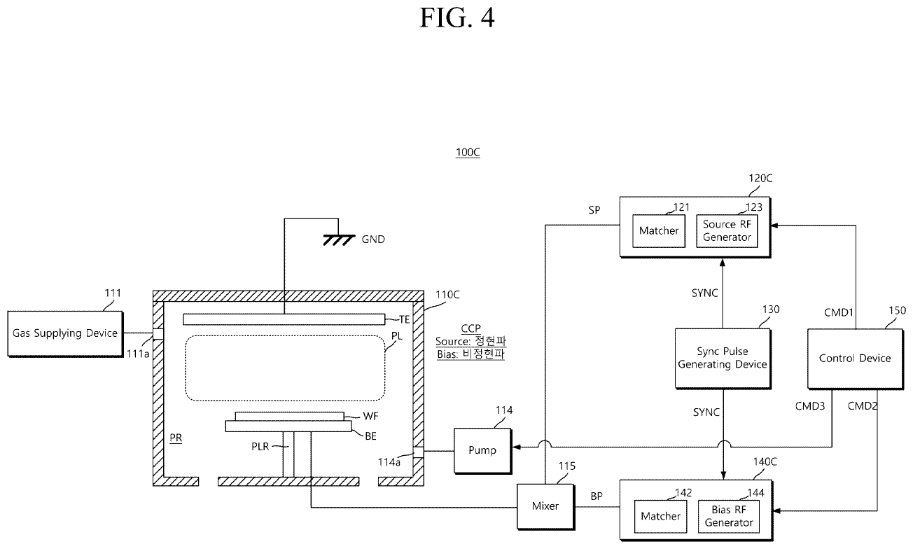

FIG. 4 is a block diagram describing a plasma processing apparatus 100C implemented as a CCP processing apparatus according to one embodiment of the present invention. The plasma processing apparatus 100C of FIG. 4 may correspond to the plasma processing apparatus 100 of FIG. 1. Referring to FIG. 4, the plasma processing apparatus 100C according to one embodiment of the present invention will be described. Detailed description of portions overlapping or similar to those described with reference to FIGS. 1 to 3 will be omitted. The plasma processing apparatus 100C will be described with reference to FIG. 4 by focusing on differences from the plasma processing apparatuses 100, 100A, and 100B of FIGS. 1 to 3.

Referring to FIG. 4, the plasma processing apparatus 100C shows a capacitive coupled plasma (CCP) processing apparatus in which ground potential is applied to the top electrode TE and the source power SP and the bias power BP are applied to the bottom electrode BE.

A source power supplying device 120C may generate the source power SP in a form of a pulse-modulated sinusoidal wave and supply the source power SP to the mixer 115.

Unlike the bias power supplying device 140B according to the embodiment of FIG. 3, a bias power supplying device 140C according to the embodiment of FIG. 4 may generate the bias power BP in a form of a pulse-modulated sinusoidal wave and supply the bias power BP to the mixer 115.

That is, the bias power supplying device 140C may include a matcher circuit 142 and a bias RF generator 144 instead of the modulator 141 and the DC power supplier 143 of FIG. 3. For example, the bias RF generator 144 may generate a bias RF signal in a form of a sinusoidal wave, and the matcher circuit 142 may match the impedance of the generated bias RF signal and then supply the matched bias RF signal to the mixer 115.

The mixer 115 may apply a signal that mixes the source power SP and the bias power BP to the bottom electrode BE.

Similar to the embodiment described with reference to FIG. 2, the bias power supplying device 140C according to an embodiment of the present invention may generate the bias power BP so that the on-duty state of the bias power BP is located in at least a portion of the on-duty state of the source power SP and at least a portion of the off-duty state of the source power SP.

The mixer 115 may supply the bottom electrode BE with a signal that mixes the bias power BP of the on-duty state and the source power SP of the on-duty state in a first time portion and supply the bottom electrode BE with a signal that mixes the bias power BP of the on-duty state and the source power SP of the off-duty state in a second time interval.

The plasma processing apparatus 100C may control the exhaust device 114 to perform exhausting of a chamber 110C in at least a portion of the off-duty state of the source power SP and at least a portion of the off-duty state of the bias power BP. In one embodiment, in order to perform the exhausting of the chamber 110C, the exhaust device 114 may receive a sync pulse SYNC from the sync pulse generating device 130 and receive the control command CMD3 including a delay time and an on-duty state duration time of the bias power BP from the control device 150.

The bias power supplying device 140C may receive the control command CMD2 including the delay time and the on-duty state duration time of the bias power BP from the control device 150. Based on the control command CMD2 received from the control device 150, the bias power supplying device 140C may supply the chamber 110C with the bias power BP having the on-duty state during the on-duty state duration time after the delay time from a rising edge of the sync pulse SYNC.

The plasma processing apparatus 100C can perform plasma processing more effectively by using each of the positive ions and the negative ions for plasma processing. In addition, the plasma processing apparatus 100C can prevent plasma processing efficiency from being degraded by the positive charges charged on the substrate by performing the plasma processing by the negative ions following the plasma processing by the positive ions.

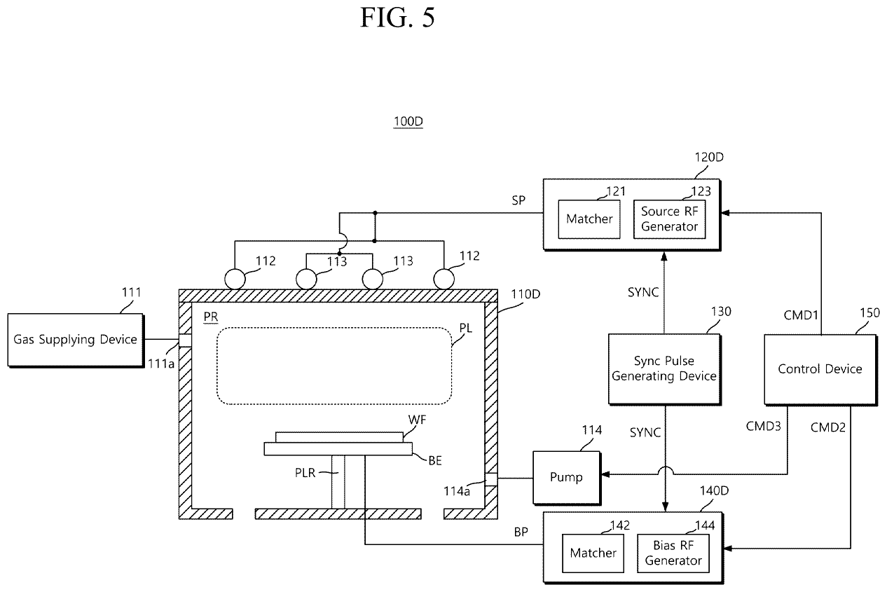

FIG. 5 is a block diagram describing a plasma processing apparatus 100D implemented as an inductively coupled plasma (ICP) processing apparatus according to one embodiment of the present invention. The plasma processing apparatus 100D of FIG. 5 may correspond to the plasma processing apparatus 100 of FIG. 1. Referring to FIG. 5, the plasma processing apparatus 100D according to one embodiment of the present invention will be described. Detailed description of portions overlapping or similar to those described with reference to FIGS. 1 to 4 will be omitted. The plasma processing apparatus 100D will be described with reference to FIG. 5 by focusing on differences from the plasma processing apparatuses 100, 100A, 100B, and 100C of FIGS. 1 to 4.

Referring to FIG. 5, the plasma processing apparatus 100D shows an inductively coupled plasma (ICP) processing apparatus in which the source power SP is applied to the plurality of coils 112 and 113 and the bias power BP is applied to the bottom electrode BE.

A source power supplying device 120D may generate the source power SP in a form of a pulse-modulated sinusoidal wave and supply the source power SP to the plurality of coils 112 and 113.

Unlike the bias power supplying device 140A according to the embodiment of FIG. 2, a bias power supplying device 140D according to the embodiment of FIG. 5 may generate the bias power BP in a form of a pulse-modulated sinusoidal wave and supply the bias power BP to the bottom electrode BE.

The bias power supplying device 140D according to an embodiment of the present invention, similar to the embodiment described with reference to FIG. 2, may supply the bias power BP to the bottom electrode BE so that the on-duty state of the bias power BP is located in at least a portion of the on-duty state the source power SP and at least a portion of the off-duty state of the source power SP.

The plasma processing apparatus 100D may control the exhaust device 114 to perform exhausting of a chamber 110D in at least a portion of the off-duty state of the source power SP and at least a portion of the off-duty state of the bias power BP. In one embodiment, in order to perform the exhausting of the chamber 110D, the exhaust device 114 may receive a sync pulse SYNC from the sync pulse generating device 130 and receive the control command CMD3 including a delay time and an on-duty state duration time of the bias power BP from the control device 150.

The bias power supplying device 140D may receive the control command CMD2 including the delay time and the on-duty state duration time of the bias power BP from the control device 150. Based on the control command CMD2 received from the control device 150, the bias RF generator 144 of the bias power supplying device 140D may generate a bias RF signal in a form of a sinusoidal wave having the on-duty state during the on-duty state duration time after the delay time from a rising edge of the sync pulse SYNC. The matcher circuit 142 may match the impedance of the generated bias RF signal and then supply the matched bias power BP to the bottom electrode BE of the chamber 110D. The plasma processing apparatus 100D can perform plasma processing more effectively by using each of the positive ions and the negative ions for plasma processing. In addition, the plasma processing apparatus 100D can prevent plasma processing efficiency from being degraded by the positive charges charged on the substrate by performing the plasma processing by the negative ions following the plasma processing by the positive ions.

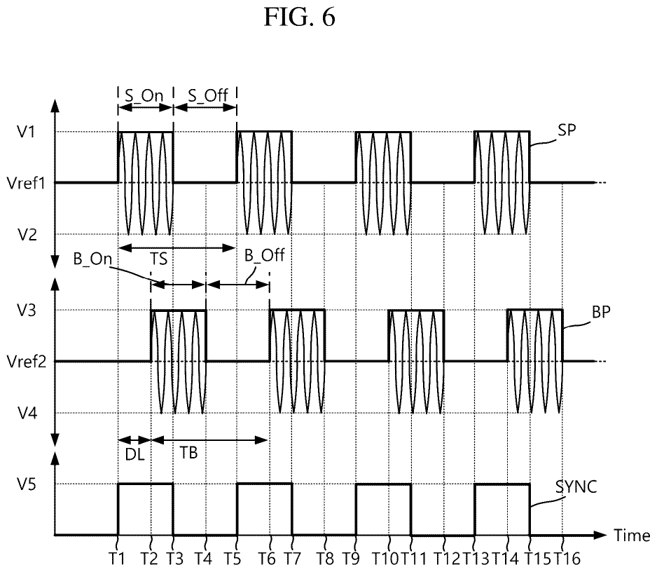

FIG. 6 is a diagram describing the source power SP, the bias power BP, and the sync pulse SYNC according to one embodiment of the present invention. The source power SP, the bias power BP, and the sync pulse SYNC according to the embodiment of FIG. 6 may be used in a plasma processing apparatus that supplies the source power SP in a form of a pulse-modulated sinusoidal wave and the bias power BP in a form of a pulse-modulated sinusoidal wave to the chamber. For example, the source power SP, the bias power BP, and the sync pulse SYNC of FIG. 6 may be used in the plasma processing apparatuses of FIGS. 4 and 5.

Referring to FIG. 6, the source power SP, the bias power BP, and the sync pulse SYNC according to one embodiment of the present invention will be described.

Referring to FIG. 6, the source power SP has two states, and the bias power BP has two states. That is, the source power SP includes one on-duty state S_On and one off-duty state S_Off per cycle TS. In addition, the bias power BP includes one on-duty state B_On and one off-duty state B_Off per cycle TB.

The sync pulse SYNC may be supplied to the source power supplying device and the bias power supplying device as a pulse of one cycle of a fifth positive voltage from time point T1 to time point T3 and a zero voltage from time point T3 to time point T5. Thereafter, the sync pulse SYNC may have the repeated pulse of the same cycle.

The source power supplying device may be triggered by a rising edge of the sync pulse SYNC to supply the chamber with the source power SP of the on-duty state S_On. The source power supplying device may supply the chamber with the source power SP synchronized to the sync pulse SYNC. That is, the cycle TS of the source power SP is the same as that of the sync pulse SYNC. The source power supplying device may supply the chamber with the source power SP of the on-duty state S_On from the rising edge of the sync pulse SYNC and supply the chamber with the source power SP of the off-duty state S_Off from a falling edge of the sync pulse SYNC. Therefore, a pulse-modulated sinusoidal wave of one cycle of a first positive voltage V1 from time point T1 to time point T3 and a first reference voltage Vref1 from time point T3 to time point T5 may be supplied to the chamber. Thereafter, the source power SP may have a repeated pulse-modulated sinusoidal wave of the same cycle.

The bias power supplying device may supply the chamber with the bias power BP of the on-duty state B_On after a delay time DL from the rising edge of the sync pulse SYNC. The cycle TB of the bias power BP is the same as the cycle TS of the source power SP. Therefore, a pulse-modulated sinusoidal wave of one cycle of a third positive voltage V3 from time point T2 to time point T4 and a second reference voltage Vref2 from time point T4 to time point T6 may be supplied to the chamber. Thereafter, the bias power BP may have a repeated pulse-modulated sinusoidal wave of the same cycle.

Referring to FIG. 6, from time point T1 to time point T2, the source power supplying device may supply the chamber with the source power SP of the on-duty state S_On and the bias power supplying device may supply the chamber with the bias power BP of the off-duty state B_Off. Therefore, only the source power SP of the on-duty state S_On may be supplied to the chamber.

From time point T2 to time point T3, the source power supplying device may supply the chamber with the source power SP of the on-duty state S_On and the bias power supplying device may supply the chamber with the bias power BP of the on-duty state B_On. Therefore, the source power SP of the on-duty state S_On and the bias power BP of the on-duty state B_On may be supplied to the chamber.

From time point T3 to time point T4, the source power supplying device may supply the chamber with the source power SP of the off-duty state S_Off and the bias power supplying device may supply the chamber with the bias power BP of the on-duty state B_On. Therefore, the source power SP of the off-duty state S_Off and the bias power BP of the on-duty state B_On may be supplied to the chamber. In this portion, negative ions may be used for plasma processing.

From time point T4 to time point T5, the source power supplying device may supply the chamber with the source power SP of the off-duty state S_Off and the bias power supplying device may supply the chamber with the bias power BP of the off-duty state B_Off. Therefore, the source power SP of the off-duty state S_Off and the bias power BP of the off-duty state B_Off may be supplied to the chamber. In this portion, the exhaust device may exhaust by-products inside the chamber.

The bias power supplying device may supply the chamber with the bias power BP of the on-duty state B_On for a predetermined time from a time point at which the delay time DL has elapsed after a time point at which the source power SP of the on-duty state S_On is supplied. That is, the bias power BP of the on-duty state B_On is supplied to the chamber only in a portion of the on-duty state S_On of the source power SP. Thereafter, the bias power BP of the on-duty state B_On is also supplied to the chamber in a portion of the off-duty state S_Off of the source power SP for a predetermined time. Therefore, the plasma processing apparatus may perform the plasma processing by the negative ions following the plasma processing by positive ions. In addition, since the bias power BP of the on-duty state B_On is supplied to the chamber only in a portion of the on-duty state S_On of the source power SP, the bias power BP of a higher voltage magnitude can be used.

In addition, the plasma processing apparatus may perform exhausting of the chamber in a portion in which the source power SP of the off-duty state S_Off and the bias power BP of the off-duty state B_Off are supplied.

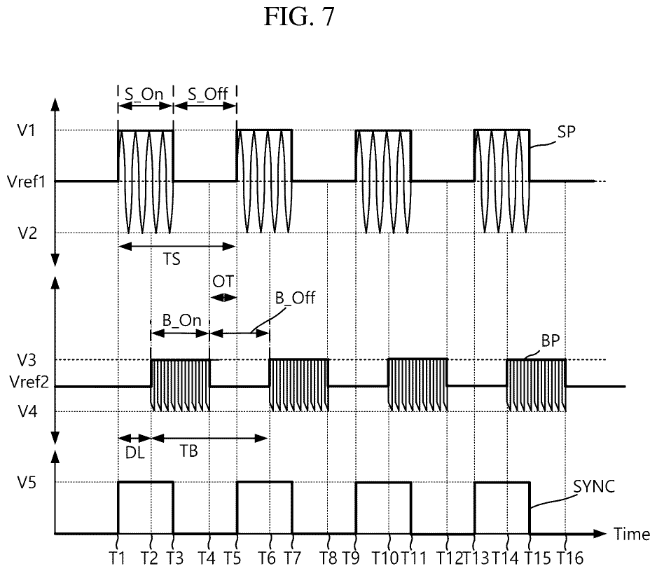

FIG. 7 is a diagram describing the source power SP, the bias power BP, and the sync pulse SYNC according to one embodiment of the present invention. The source power SP, the bias power BP, and the sync pulse SYNC according to the embodiment of FIG. 7 may be used in a plasma processing apparatus that supplies the source power SP in a form of a pulse-modulated sinusoidal wave and the bias power BP in a form of a pulse-modulated non-sinusoidal wave to the chamber. For example, the source power SP, the bias power BP, and the sync pulse SYNC of FIG. 7 may be used in the plasma processing apparatuses of FIGS. 2 and 3.

Referring to FIG. 7, the source power SP, the bias power BP, and the sync pulse SYNC according to one embodiment of the present invention will be described. Detailed description of portions overlapping or similar to those described with reference to FIG. 6 will be omitted, and differences will be mainly described.

The sync pulse SYNC and the source power SP of FIG. 7 are identical to the sync pulse SYNC and the source power SP of FIG. 6, respectively.

Referring to FIG. 7, the source power SP has two states, and the bias power BP has two states. That is, the source power SP includes one on-duty state S_On and one off-duty state S_Off per the cycle TS. In addition, the bias power BP includes one on-duty state B_On and one off-duty state B_Off per the cycle TB.

Referring to FIG. 7, the source power SP has two states, and the bias power BP has two states. That is, the source power SP includes one on-duty state S_On and one off-duty state S_Off per the cycle TS. In addition, the bias power BP includes one on-duty state B_On and one off-duty state B_Off per the cycle TB.

Referring to FIG. 7, unlike the bias power BP of FIG. 6, the bias power BP has a form of a pulse-modulated non-sinusoidal wave including a pulse portion having a positive bias voltage and a ramp portion having a negative bias voltage varying with a negative slope.

In the bias power BP of FIG. 7, similar to the bias power BP of FIG. 6, the bias power BP of the on-duty state B_On may be supplied to the chamber for a predetermined time from a time point at which the delay time DL has elapsed after a time point at which the source power SP of the on-duty state S_On is supplied. That is, the bias power BP of the on-duty state B_On is supplied to the chamber only in a portion of the on-duty state S_On of the source power SP. Thereafter, the bias power BP of the on-duty state B_On is also supplied to the chamber in a portion of the off-duty state S_Off of the source power SP for a predetermined time. Therefore, the plasma processing apparatus may perform the plasma processing by the negative ions following the plasma processing by the positive ions. In addition, since the bias power BP of the on-duty state B_On is supplied to the chamber only in a portion of the on-duty state S_On of the source power SP, the bias power BP of a higher voltage magnitude may be used.

In addition, the plasma processing apparatus may perform exhausting of the chamber in a portion in which the source power SP of the off-duty state S_Off and the bias power BP of the off-duty state B_Off are supplied.

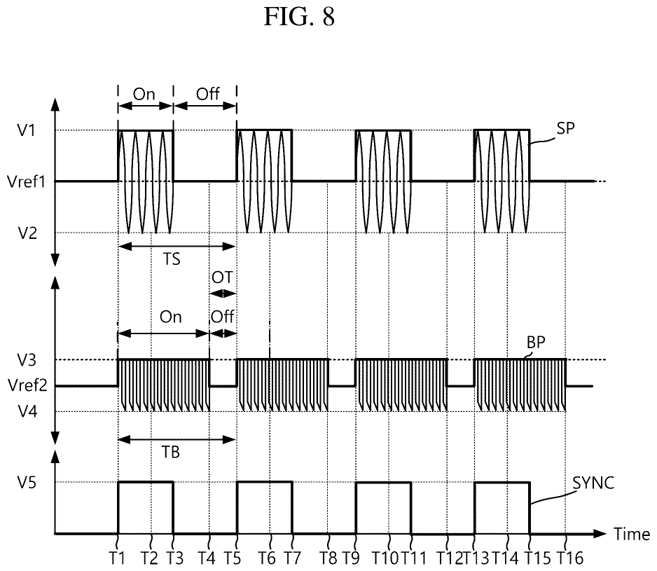

FIG. 8 is a diagram describing the source power SP, the bias power BP, and the sync pulse SYNC according to one embodiment of the present invention. The source power SP, the bias power BP, and the sync pulse SYNC according to the embodiment of FIG. 8 may be used in a plasma processing apparatus that supplies the source power SP in a form of a pulse-modulated sinusoidal wave and the bias power BP in a form of a pulse-modulated non-sinusoidal wave to the chamber. For example, the source power SP, the bias power BP, and the sync pulse SYNC of FIG. 8 may be used in the plasma processing apparatuses of FIGS. 2 and 3.

Referring to FIG. 8, the source power SP, the bias power BP, and the sync pulse SYNC according to one embodiment of the present invention will be described. Detailed description of portions overlapping or similar to those described with reference to FIGS. 6 and 7 will be omitted, and differences will be mainly described.

The sync pulse SYNC and the source power SP of FIG. 8 are identical to the sync pulse SYNC and the source power SP of FIGS. 6 and 7, respectively.

Referring to FIG. 8, the source power SP has two states, and the bias power BP has two states. That is, the source power SP includes one on-duty state S_On and one off-duty state S_Off per the cycle TS. In addition, the bias power BP includes one on-duty state B_On and one off-duty state B_Off per the cycle TB.

Referring to FIG. 8, similar to the bias power BP of FIG. 7, the bias power BP has a form of a pulse-modulated non-sinusoidal wave including a pulse portion having a positive bias voltage and a ramp portion having a negative bias voltage varying with a negative slope.

In the bias power BP of FIG. 8, unlike the bias power BP of FIG. 7, the bias power BP of the on-duty state B_On may be supplied to the chamber for a predetermined time from a time point at which the source power SP of the on-duty state S_On is supplied. That is, the bias power BP of the on-duty state B_On is supplied to the chamber in all portions of the on-duty state S_On of the source power SP. Thereafter, the bias power BP of the on-duty state B_On is also supplied in a portion of the off-duty state S_Off of the source power SP for a predetermined time. Therefore, the plasma processing apparatus may perform the plasma processing by the negative ions following the plasma processing by the positive ions. In addition, since the bias power BP of the on-duty state B_On in all portions of the on-duty state S_On of the source power SP is supplied to the chamber, the bias power BP of a lower voltage magnitude can be used.

In addition, the plasma processing apparatus may perform exhausting of the chamber in a portion in which the source power SP of the off-duty state S_Off and the bias power BP of the off-duty state B_Off are supplied.

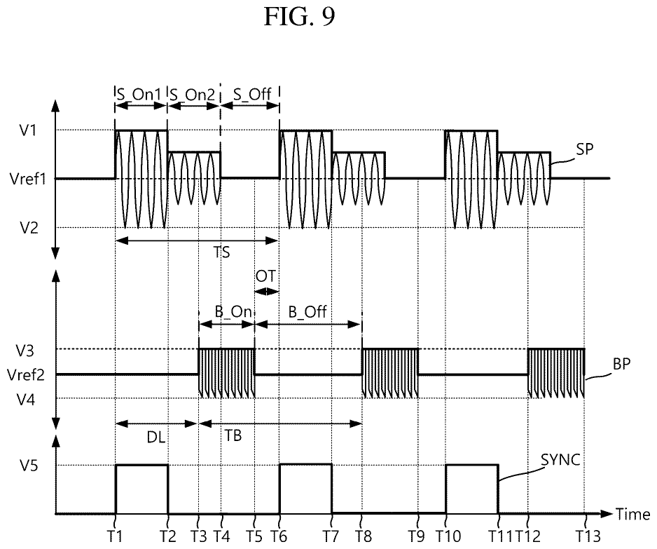

FIG. 9 is a diagram describing the source power SP, the bias power BP, and the sync pulse SYNC according to one embodiment of the present invention. The source power SP, the bias power BP, and the sync pulse SYNC according to the embodiment of FIG. 9 may be used in a plasma processing apparatus that supplies the source power SP in a form of a pulse-modulated sinusoidal wave and the bias power BP in a form of a pulse-modulated non-sinusoidal wave to the chamber. For example, the source power SP, the bias power BP, and the sync pulse SYNC of FIG. 9 may be used in the plasma processing apparatuses of FIGS. 2 and 3.

Referring to FIG. 9, the source power SP, the bias power BP, and the sync pulse SYNC according to one embodiment of the present invention will be described. Detailed description of portions overlapping or similar to those described with reference to FIGS. 6 to 8 will be omitted, and differences will be mainly described.

The sync pulse SYNC of FIG. 9 is the same as the sync pulse SYNC of FIGS. 6 to 8.

Referring to FIG. 9, unlike the source power SP of FIGS. 6 to 8, the source power SP has three states and the bias power BP has two states. That is, the source power SP includes two on-duties S_On1 and S_On2, and one off-duty state S_Off per the cycle TS. In addition, the bias power BP includes one on-duty state B_On and one off-duty state B_Off per the cycle TB.

Referring to FIG. 9, similar to the bias power BP of FIG. 7, the bias power BP has a form of a pulse-modulated non-sinusoidal wave including a pulse portion having a positive bias voltage and a ramp portion having a negative bias voltage varying with a negative slope.

Referring to FIG. 9, from time point T1 to time point T2, the source power SP of a first on-duty state S_On1 is supplied to the chamber, and from time point T2 to time point T4, the source power SP of a second on-duty state S_On2 is supplied to the chamber. From time point T4 to time point T6, the source power SP of the off-duty state S_Off is supplied to the chamber. That is, the source power SP of the first on-duty state S_On1 and the source power SP of the second on-duty state S_On2 are supplied to the chamber a form that is connected to each other. As such, the first on-duty state and the second on-duty state are contiguous. A voltage amplitude of the source power SP of the first on-duty state S_On1 may be greater than a voltage magnitude of the source power SP of the second on-duty state S_On2.

The bias power BP may be supplied to the chamber in a portion of the second on-duty state S_On2 of the source power SP and a portion of the off-duty state S_Off of the source power SP. That is, the bias power BP of the on-duty state B_On is supplied to the chamber for a predetermined time from time point T3, which is after time point T2 at which the source power SP of the second on-duty state S_On2 begins to be supplied to the chamber, to time point T5 at which the source power SP of the off-duty state S_Off is supplied.

Therefore, the plasma processing apparatus may perform the plasma processing by the negative ions following the plasma processing by the positive ions. In addition, since the bias power BP of the on-duty state B_On is supplied to the chamber in a portion of the second on-duty state S_On2 of the source power SP, the bias power BP of a relatively higher voltage magnitude can be used.

In addition, the plasma processing apparatus may perform exhausting of the chamber in a portion in which the source power SP of the off-duty state S_Off and the bias power BP of the off-duty state B_Off are supplied.

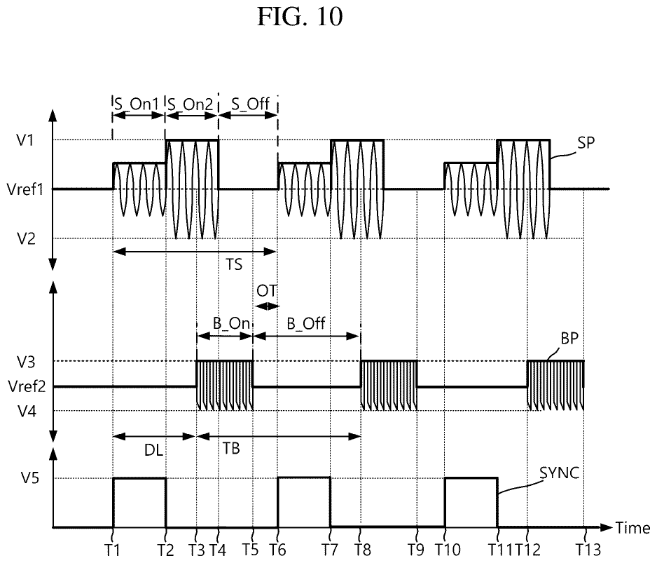

FIG. 10 is a diagram describing the source power SP, the bias power BP, and the sync pulse SYNC according to one embodiment of the present invention. The source power SP, the bias power BP, and the sync pulse SYNC according to the embodiment of FIG. 10 may be used in a plasma processing apparatus that supplies the source power SP in a form of a pulse-modulated sinusoidal wave and the bias power BP in a form of a pulse-modulated non-sinusoidal wave to the chamber. For example, the source power SP, the bias power BP, and the sync pulse SYNC of FIG. 10 may be used in the plasma processing apparatuses of FIGS. 2 and 3.

Referring to FIG. 10, the source power SP, the bias power BP, and the sync pulse SYNC according to one embodiment of the present invention will be described. Detailed description of portions overlapping or similar to those described with reference to FIGS. 6 to 9 will be omitted, and differences will be mainly described.

The sync pulse SYNC of FIG. 10 is the same as the sync pulse SYNC of FIGS. 6 to 9.

Referring to FIG. 10, similar to the source power SP of FIG. 9, the source power SP has three states and the bias power BP has two states. That is, the source power SP includes two on-duties S_On1 and S_On2, and one off-duty state S_Off per the cycle TS. In addition, the bias power BP includes one on-duty state B_On and one off-duty state B_Off per the cycle TB.

Referring to FIG. 10, similar to the bias power BP of FIG. 7, the bias power BP has a form of a pulse-modulated non-sinusoidal wave including a pulse portion having a positive bias voltage and a ramp portion having a negative bias voltage varying with a negative slope.

Referring to FIG. 10, unlike the source power SP in FIG. 9, a voltage magnitude of the source power SP of the first on-duty state S_On1 may be smaller than a voltage magnitude of the source power SP of the second on-duty state S_On2.

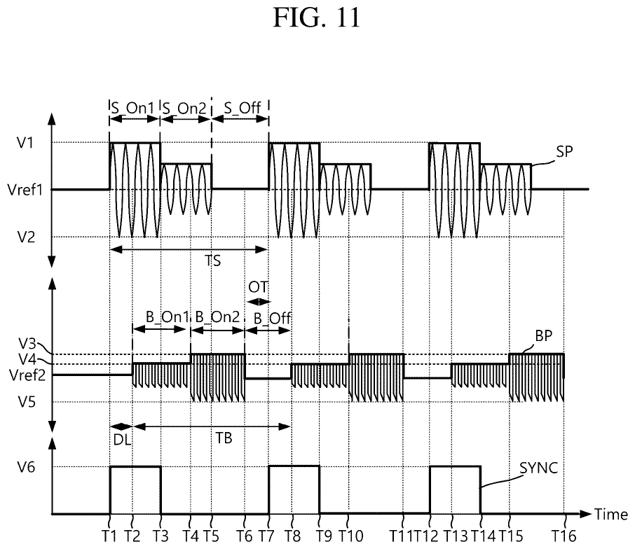

FIG. 11 is a diagram describing the source power SP, the bias power BP, and the sync pulse SYNC according to one embodiment of the present invention. The source power SP, the bias power BP, and the sync pulse SYNC according to the embodiment of FIG. 11 may be used in a plasma processing apparatus that supplies the source power SP in a form of a pulse-modulated sinusoidal wave and the bias power BP in a form of a pulse-modulated non-sinusoidal wave to the chamber. For example, the source power SP, the bias power BP, and the sync pulse SYNC of FIG. 11 may be used in the plasma processing apparatuses of FIGS. 2 and 3.

Referring to FIG. 11, the source power SP, the bias power BP, and the sync pulse SYNC according to one embodiment of the present invention will be described. Detailed description of portions overlapping or similar to those described with reference to FIGS. 6 to 10 will be omitted, and differences will be mainly described.

The sync pulse SYNC of FIG. 11 is the same as the sync pulse SYNC of FIGS. 6 to 10. The source power SP of FIG. 11 is the same as the source power SP of FIG. 9.

Referring to FIG. 11, unlike the embodiments in FIGS. 6 to 9, the bias power BP has three states. That is, the bias power BP includes two on-duties B_On1 and B_On2 and one off-duty state B_Off per the cycle TB.

Referring to FIG. 11, the source power SP includes the first on-duty state S_On1, the second on-duty state S_On2, and the off-duty state S_Off, and the bias power BP includes a third on-duty state B_On1, a fourth on-duty state B_On2, and the off-duty state B_Off.

A voltage amplitude of the source power SP of the first on-duty state S_On1 may be greater than a voltage magnitude of the source power SP of the second on-duty state S_On2. A voltage amplitude of the bias power BP of the third on-duty state B_On1 may be smaller than a voltage magnitude of the fourth on-duty state B_On2.

Referring to FIG. 11, similar to the bias power BP of FIG. 7, the bias power BP has a form of a pulse-modulated non-sinusoidal wave including a pulse portion having a positive bias voltage and a ramp portion having a negative bias voltage varying with a negative slope.

The bias power supplying device may be configured to supply the chamber with the bias power BP of the third on-duty state B_On1 in a portion of the first on-duty state S_On1 of the source power SP (e.g., from time point T2 to time point T3) and a portion of the second on-duty state S_On2 of the source power SP (e.g., from time point T3 to time point T4).

The bias power supplying device may be configured to supply the chamber with the bias power BP of the fourth on-duty state B_On2 in a portion of the second on-duty state S_On2 of the source power SP (e.g., from time point T4 to time point T5) and a portion of the off-duty state S_Off of the source power SP (e.g., from time point T5 to time point T6).

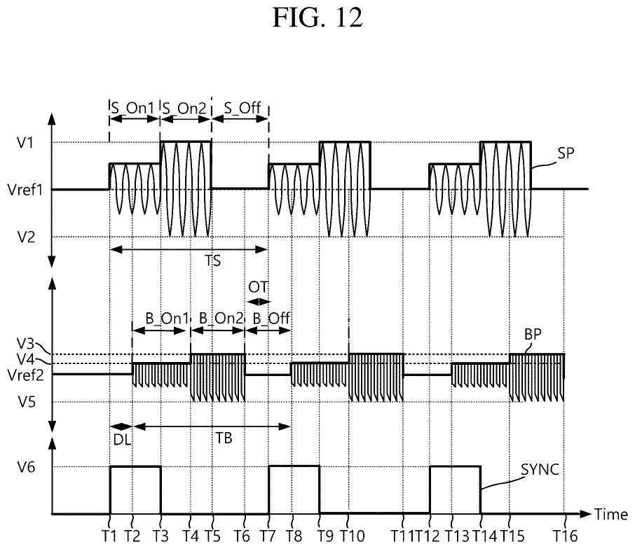

FIG. 12 is a diagram describing the source power SP, the bias power BP, and the sync pulse SYNC according to one embodiment of the present invention. The source power SP, the bias power BP, and the sync pulse SYNC according to the embodiment of FIG. 12 may be used in a plasma processing apparatus that supplies the source power SP in a form of a pulse-modulated sinusoidal wave and the bias power BP in a form of a pulse-modulated non-sinusoidal wave to the chamber. For example, the source power SP, the bias power BP, and the sync pulse SYNC of FIG. 12 may be used in the plasma processing apparatuses of FIGS. 2 and 3.

Referring to FIG. 12, the source power SP, the bias power BP, and the sync pulse SYNC according to one embodiment of the present invention will be described. Detailed description of portions overlapping or similar to those described with reference to FIGS. 6 to 11 will be omitted, and differences will be mainly described.

The sync pulse SYNC and the bias power BP of FIG. 12 are the same as the sync pulse SYNC and the bias power BP of FIG. 11.

Referring to FIG. 12, the source power SP and the bias power BP have three states. That is, the source power SP includes two on-duties S_On1 and S_On2 and one off-duty state S_Off per the cycle TS, and the bias power BP consists of two on-duties B_On1 and B_On2 and one off-duty state B_Off per the cycle TB.

Referring to FIG. 12, the source power SP includes the first on-duty state S_On1, the second on-duty state S_On2, and the off-duty state S_Off, and the bias power BP includes the third on-duty state B_On1, the fourth on-duty state B_On2, and the off-duty state B_Off.

Referring to FIG. 12, a voltage amplitude of the source power SP of the first on-duty state S_On1 may be smaller than a voltage magnitude of the second on-duty state S_On2. A voltage amplitude of the bias power BP of the third on-duty state B_On1 may be smaller than a voltage magnitude of the fourth on-duty state B_On2.

Referring to FIG. 12, similar to the bias power BP of FIG. 7, the bias power BP has a form of a pulse-modulated non-sinusoidal wave including a pulse portion having a positive bias voltage and a ramp portion having a negative bias voltage varying with a negative slope.

The bias power supplying device, similar to FIG. 11, may be constituted to supply the chamber with the bias power BP of the third on-duty state B_On1 in a portion of the first on-duty state S_On1 of the source power SP (e.g., from time point T2 to time point T3) and a portion of the second on-duty state S_On2 of the source power SP (e.g., from time point T3 to time point T4).

The bias power supplying device, similar to FIG. 11, may be constituted to supply the chamber with the bias power BP of the fourth on-duty state B_On2 in a portion of the second on-duty state S_On2 of the source power SP (e.g., from time point T4 to time point T5) and a portion of the off-duty state S_Off of the source power SP (e.g., from time point T5 to time point T6).

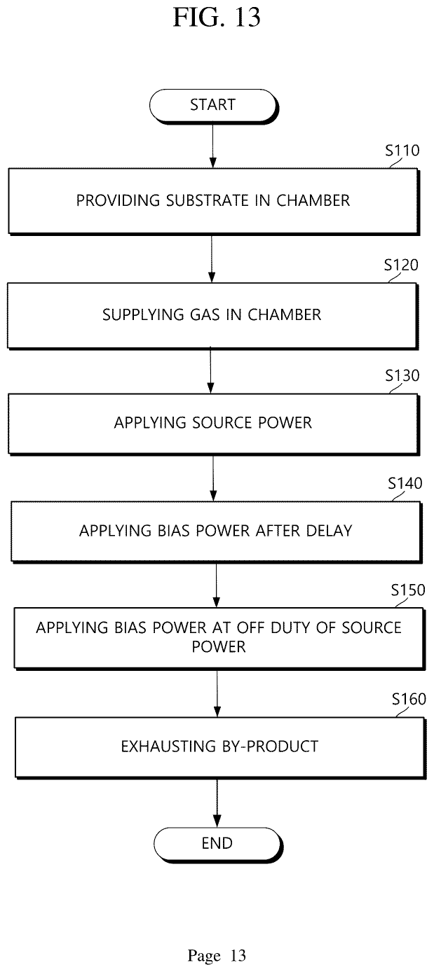

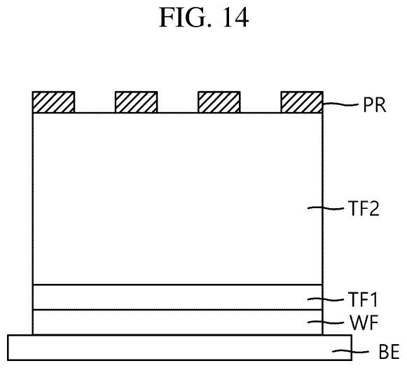

FIG. 13 is a flowchart describing a plasma processing method according to one embodiment of the present invention, and FIGS. 14 to 16 are views describing some operations of a plasma processing method according to an embodiment of the present invention.

Referring to FIGS. 13 to 16, a plasma processing method of a plasma processing apparatus will be described. The plasma processing method of FIG. 13 may be performed in the plasma processing apparatuses 100, 100A, 100B, 100C, and 100D of FIGS. 1 to 5.

Referring to FIG. 13, in operation S110, the plasma processing apparatuses 100, 100A, 100B, 100C, and 100D may provide a substrate to a processing space of a chamber.

The substrate to be plasma-processed may include a semiconductor substrate WF, a thin film TF1 on the semiconductor substrate, and an etching target film TF2 on the thin film TF1. In some implementations, the thin film TF1 and/or the etching target film TF2 may be omitted. The substrate may be disposed on an electrostatic chuck including a bottom electrode BE.

A photoresist PR for forming a semiconductor pattern may be disposed on the etching target film TF2.

In operation S120, gas for plasma processing may be supplied to the processing space in the chamber.

In operation S130, source power may be supplied to the chamber by a source power supplying device. According to the implementation examples, the source power may be mixed with a bias power and supplied to the chamber. By supplying the source power, plasma may be generated from the gas in the processing space. The source power may be a pulse-modulated sinusoidal wave. The source power may have two states or three states. For example, the source power may be the source powers SP of any one of the embodiments of FIGS. 6 to 12.

In operation S140, after a predetermined delay time after the source power of an on-duty state is supplied, the bias power of an on-duty state may be supplied to the chamber. According to the implementation examples, the bias power may be a pulse-modulated sinusoidal wave or a non-sinusoidal wave. The bias power may have two states or three states. For example, the bias power may be the bias powers BP of any one of the embodiments of FIGS. 6 to 12. The bias power may maintain the on-duty state in at least a portion of the on-duty state and at least a portion of an off-duty state of the source power. Therefore, the plasma processing apparatuses 100, 100A, 100B, 100C, and 100D can perform not only plasma processing using positive ions but also plasma processing using negative ions.

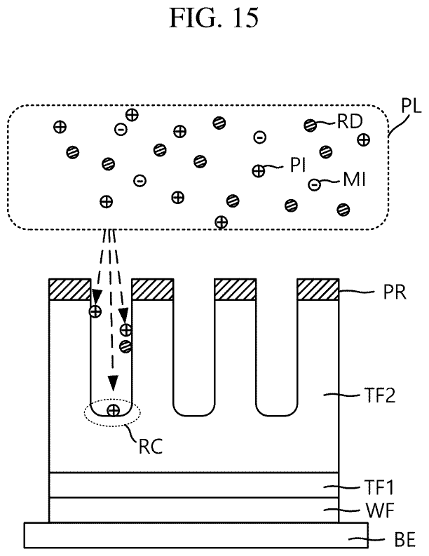

FIG. 15 shows that in an adoptable related technology, plasma PL includes positive ions PI, negative ions MI, and an active species RD. Referring to FIG. 15, in the related technology, positive charges may be charged at the lowest portion of a depth RC due to the positive ions PI and as plasma processing is performed, the positive ions PI that reach the lowest portion of the depth RC may decrease.

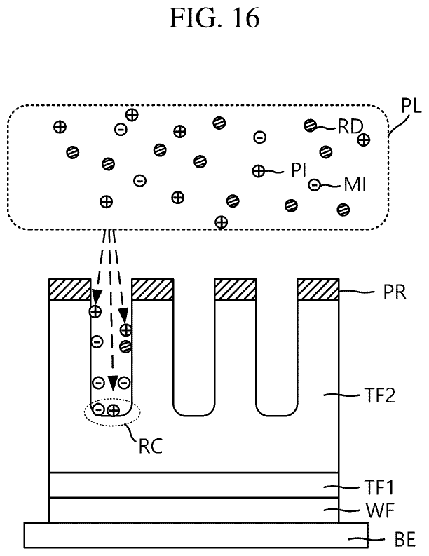

In contrast, referring to FIG. 16, in the plasma processing method according to an embodiment of the present invention, since the bias power maintains the on-duty state in at least a portion of the off-duty state of the source power, the negative ions MI can be used for the plasma processing and the positive charges charged at the lowest portion of the depth RC may be neutralized by the negative ions MI. Therefore, even when the source power of the next cycle is used for plasma processing, it is possible to prevent plasma processing efficiency from being degraded by the positive charges.

In operation S150, the bias power supplying device may supply the chamber with the bias power of the off-duty state. The bias power may maintain the off-duty state in a portion of the off-duty state of the source power.

In operation S160, in at least a portion among portions in which both the source power and the bias power maintain the off-duty state, the plasma processing apparatuses 100, 100A, 100B, 100C, and 100D may perform exhausting of the chamber.

A plasma processing apparatus and a plasma processing method according to embodiments of the present invention can form a fine structure of a semiconductor device with high reliability.

A plasma processing apparatus and a plasma processing method according to embodiments of the present invention can increase plasma processing efficiency by effectively utilizing negative ions to perform plasma processing.

Meanwhile, the above-described contents are specific embodiments for implementing the present invention. In addition to the above-described embodiments, the present invention will also include embodiments that can be simply designed around or easily changed. In addition, the present invention will also include technologies that can be easily modified and implemented using the embodiments. Therefore, the scope of the present invention should not be limited to the above-described embodiments, but should be defined not only by the patent claims described below but also by the equivalents of the claims of this invention.

What is claimed is:

1. A plasma processing apparatus comprising:
a chamber configured to host a substrate;
a source power supplying device configured to generate a plasma in the chamber by supplying the chamber with source power comprising a pulsed wave such that the source power has an on-duty state and an off-duty state; and
a bias power supplying device configured to control a polarity of the plasma by supplying the chamber with bias power in at least a portion of the on-duty state of the source power and at least a portion of the off-duty state of the source power.

2. The plasma processing apparatus of claim 1, further comprising an exhaust device configured to exhaust the chamber during a subportion of the portion of the off-duty state in which the bias power is in an off-duty state.

3. The plasma processing apparatus of claim 1, wherein:
the bias power comprises a pulse-modulated sinusoidal wave or a pulse-modulated non-sinusoidal wave.

4. The plasma processing apparatus of claim 3, wherein:
the pulse-modulated non-sinusoidal wave comprises a pulse portion having a positive bias voltage and a ramp portion having a negative bias voltage varying with a negative slope.

5. The plasma processing apparatus of claim 1, wherein:
the source power supplying device is configured to supply the chamber with the source power having three states, and
the bias power supplying device is configured to supply the chamber with the bias power having two states or three states.

6. The plasma processing apparatus of claim 5, wherein:
the three states of the source power comprise a first on-duty state, a second on-duty state, and the off-duty state,
the two states of the bias power comprises an on-duty state and an off-duty state, and
the bias power supplying device is configured to supply the chamber with the bias power in the on-duty state in at least portion of the second on-duty state of the source power and at least a portion of the off-duty state of the source power.

7. The plasma processing apparatus of claim 6, wherein:
the first on-duty state of the source power and the second on-duty state of the source power are contiguous, and a voltage magnitude of the source power in the first on-duty state differs from a voltage magnitude of the source power in the second on-duty state.

8. The plasma processing apparatus of claim 5, wherein:
the three states of the power source comprise a first on-duty state, a second on-duty state, and the off-duty state,
the three states of the bias power comprise a third on-duty state, a fourth on-duty state, and an off-duty state,
the bias power supplying device is configured to supply the chamber with the bias power in the third on-duty state in at least a portion of the first on-duty state of the source power and at least a portion of the second on-duty state of the source power, and
the bias power supplying device is configured to supply the chamber with the bias power in the fourth on-duty state in at least a portion of the second on-duty state of the source power and at least a portion of the off-duty state of the source power.

9. The plasma processing apparatus of claim 8, wherein:
the first on-duty state of the source power and the second on-duty state of the source power are contiguous, and a voltage magnitude of the source power in the first on-duty state differs from a voltage magnitude of the source power in the second on-duty state, and
the third on-duty state of the bias power and the fourth on-duty state of the bias power are contiguous, and a voltage magnitude of the bias power in the third on-duty state is smaller than a voltage magnitude of the bias power in the fourth on-duty state.

10. The plasma processing apparatus of claim 1, further comprising:
a control device configured to transmit a command including a delay time to the bias power supplying device.

11. The plasma processing apparatus of claim 10, wherein:
the control device is configured to transmit a mode command based on the number of on-duty state of the bias power to the bias power supplying device.

12. The image sensor of claim 10, wherein:
the bias power supplying device is configured to supply the chamber with the bias power in an on-duty state after the delay time has elapsed from a rising edge of a sync pulse.

13. The plasma processing apparatus of claim 10, wherein:
the control device is configured to individually control an on-duty state of each of the source power and the bias power.

14. The plasma processing apparatus of claim 10, further comprising:
an exhaust device configured to perform exhausting of the chamber,
wherein the exhaust device is configured to receive a control command including the delay time and a duration time of an on-duty state of the bias power from the control device.

15. The plasma processing apparatus of claim 14, wherein:
the exhaust device is configured to receive a sync pulse from a sync pulse generating device.

16. The plasma processing apparatus of claim 14, wherein:
the exhaust device is configured to receive a trigger signal from each of the source power supplying device and the bias power supplying device and to perform exhausting of the chamber based on the trigger signal.

17. A plasma processing apparatus comprising:
a chamber configured to host a substrate;
a top electrode including a plurality of coils;
a substrate stage including a bottom electrode, the substrate stage being configured to support the substrate;
a source power supplying device configured to generate a plasma in the chamber by supplying the top electrode with source power comprising a pulsed wave such that the source power has an on-duty state and an off-duty state; and
a bias power supplying device configured to control a polarity of the plasma by supplying the bottom electrode with bias power in at least a portion of the on-duty state of the source power and at least a portion of the off-duty state of the source power.

18. The plasma processing apparatus of claim 17, wherein:
the bias power supplying device includes a direct current (DC) power supplier configured to generate a DC voltage and a modulator configured to ramp a portion of the bias power.

19. A plasma processing apparatus comprising:
a chamber configured to host a substrate;
a top electrode to which ground potential is applied;
a substrate stage including a bottom electrode, the substrate stage being configured to support the substrate;
a source power supplying device configured to generate a plasma in the chamber by generating source power comprising a pulsed wave such that the source power has an on-duty state and an off-duty state;
a bias power supplying device configured to control a polarity of the plasma by generating bias power; and
a mixer configured to generate a signal by mixing the source power and the bias power, and to apply the signal to the bottom electrode, wherein the bias power supplying device is configured to supply the bias power to the mixer in at least a portion of the on-duty state of the source power and at least a portion of the off-duty state of the source power.

20. The plasma processing apparatus of claim 19, wherein:
the mixer is configured to supply the bottom electrode with a signal that mixes the bias power in an on-duty state and the source power in the on-duty state in a first time interval and to supply the bottom electrode with a signal that mixes the bias power in the on-duty state and the source power in the off-duty state in a second time interval.
